(19) United States
(12) Patent Application Publication
(10) Pub. No.: US 2003/0037802 A1
(43) Pub. Date: Feb. 27, 2003

(54) Semiconductor treating apparatus and cleaning method of the same

(75) Inventors: Miwako Nakahara, Yokohama (JP); Toshiyuki Arai, Ome (JP); Satoshi Yamamoto, Ome (JP); Tsukasa Ohoka, Tokyo (JP); Atsushi Sano, Tokyo (JP); Hideharu Itaya, Tokyo (JP); Harunobu Sakuma, Tokyo (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/202,523

(22) Filed: Jul. 23, 2002

(30) Foreign Application Priority Data
Jul. 23, 2001 (JP) 2001-220834

(51) Int. Cl. C23F 1/00; C23C 16/00; C25F 1/00

(52) U.S. Cl. 134/1.1; 118/715; 156/345.33

(57) ABSTRACT

A ruthenium film, an osmium film, and an oxide thereof, deposited or adhered on the inside of a semiconductor treating apparatus are effectively removed. To accomplish this, an oxygen-atom donating gas and a halogen gas are supplied to the apparatus, whereby a reaction product deposited or adhered on the inside of the apparatus can be rapidly and effectively removed. In addition, to providing a stable operation, the formation of a thin film with high qualities and the production of a semiconductor device with a high yield are also realized.

### FIELD OF THE INVENTION

The present invention relates to a CVD apparatus for depositing a material containing ruthenium, ruthenium oxide, osmium or osmium oxide into a solid, or a method of cleaning an etching apparatus for pattern-forming a deposited film thereof.

With respect to a CVD (chemical vapor deposition) method, which can form a thin film which is good in adhesiveness to a wafer, as compared with a physical vapor deposition method, which is one of methods for forming an electrode material of ruthenium or ruthenium oxide, JP-A-6-283438 or JP-A-9-246214 disclose a method of depositing a specific organic source gas according to MO-CVD (metal organic chemical vapor deposition).

On the other hand, with respect to a method of etching a thin film of ruthenium or ruthenium oxide, for example, JP-A-8-78396 (corresponding to U.S. Pat. No. 5,624,583) discloses an etching method comprising using a mixed gas of oxygen gas or ozone gas, and at least one or more selected from the group consisting of fluorine gas, chlorine gas, iodine gas, a halogen gas containing at least one of said gases, and a hydrogen halide gas.

Furthermore, “Zeitschrift Fuer Naturforschung, Section B, Chemical Science, vol. 16B, No. 3, 1981, pp395” by Rainer Loessberg and Ulrich Mueller discloses a method of providing a purified ruthenium tetraoxide, comprising reacting ruthenium with ozone at room temperature.

Besides, with respect to a method of cleaning a CVD apparatus for depositing ruthenium or ruthenium oxide, and an etching apparatus for pattern-forming the deposit, JP-A-2000-200782 discloses a method of cleaning such an apparatus, comprising using at least one gas selected from the group consisting of ozone, an oxygen halide, N₂O, and oxygen atom; and a method of cleaning such an apparatus, comprising adding a halogenated gas to said gas.

### SUMMARY OF THE INVENTION

In recent years, with the higher integration of a semiconductor device, a device having a memory cell such as a DRAM (dynamic random access memory) has been more and more complicated in three-dimensional structure so as to secure the electric capacity of a condenser thereof. Therefore, the number of the manufacturing process of the above device tends to be increased, and a process margin in a step of forming a thin film or a step of processing the thin film tends to be decreased, which have given rise to an increase in the cost of production or a decrease in yield. In the light of the above background, for the purpose of increasing the storage capacity of a condenser thereof, it has been desired to simplify the structure of such a device by using a new material having a higher dielectric constant.

Currently, as this type of higher dielectric constant, multicomponent oxides, such as Ta₂O₅ and BaSrTiO₃, are earnestly studied. When these oxides are prepared, it is necessary to anneal the same at a high temperature in an atmosphere of oxygen. Therefore, when silicon, which is commonly used, is used as a lower electrode of a condenser, oxidation on the above annealing in an atmosphere of oxygen may cause the problem that the electrode is increased in value of resistance. Thus in order to realize a memory cell such as a higher integrated DRAM, it has been necessary to select such a new material as is difficult to be oxidized in an oxygen annealing-atmosphere, or is electrically conductive even if oxidized.

As electrode materials which can satisfy such conditions, for example, ruthenium and ruthenium oxide have been studied.

When a semiconductor device such as a DRAM is produced with a high yield by means of a CVD apparatus for depositing a thin film comprising ruthenium or ruthenium oxide, which is a new material, or by means of an etching apparatus for subjecting the above thin film to an etching process so as to form a desired pattern, it is necessary to decrease the occurrence of dust from the apparatuses mentioned above. Specifically, it has been desired in the industry of semiconductors to establish a method of cleaning and removing a by-product material of reaction including ruthenium, which was deposited or adhered to the inside of a reaction treatment chamber and/or a pipeline during processing, so as to prepare the following production.

One of methods of etching a film of ruthenium or ruthenium oxide as disclosed in the prior art is the one wherein a plasma-etching reaction is utilized using a mixed gas of a halogen gas and ozone gas. However, when this reaction is applied to cleaning a deposition apparatus and/or an etching apparatus, since plasma is used for pyrolyzing an etching gas, not only is it difficult to avoid a damage to an object to be processed, but an immense investment also is necessary, which forms a large problem for mass production of semiconductor devices. Furthermore, in the above method, merely an area subjected to plasma is predominantly etched, and the other area is not etched, and thus there exists the problem that the yield of semiconductor devices is decreased by the dust from the other area On the other hand, a non-plasma method, wherein a cleaning process is carried out with merely ozone gas, may provide an effective solution for preventing a damage to an object to be processed and for suppressing an investment. However, in the etching method with ozone gas, a temperature range wherein an etching process is promoted is confined, and it is difficult to etch at a relatively high temperature, and furthermore the etching method has the drawback that it is difficult to etch ruthenium oxide.

In addition, the above etching method with ozone gas has the problem that when a halogen gas is added to ozone gas, ozone gas is reacted with the halogen gas, and the amount of each of ozone gas and the halogen gas which can contribute to etch a matter to be processed is decreased, whereby the etch rate is extremely decreased.

It is an object of the present invention to provide a treating apparatus comprising a means capable of, with no residue and rapidly, removing a ruthenium film and/or a reaction product thereof as deposited or adhered on the inside of a reaction treating apparatus, so as to solve the problems and drawback mentioned above in the prior art.

In the present invention, a reaction product including ruthenium, ruthenium oxide, osmium, or osmium oxide, with a state of from a low temperature to a high temperature is removed by using a gas comprising an oxygen-atom donating gas as well as a gas comprising a halogen.

The present invention provides, as specific means for realizing the above removal, a semiconductor treating apparatus, comprising a treatment chamber, a wafer holder having a vertically movable means, a shower head, a treatment gas feeder, a first cleaning gas feeder, and a second cleaning gas feeder, wherein a treatment gas fed from this treatment gas feeder, and a first cleaning gas and a second cleaning gas fed from the first cleaning gas feeder and the second cleaning gas feeder, respectively, are fed into the treatment chamber through the shower head, and when a first cleaning gas is fed from the first cleaning gas feeder, the wafer holder is allowed to be separated from the shower head.

Furthermore, the treatment chamber can be provided with a cover member, with the inner wall of the treatment chamber covered, and each of the inner wall of the treatment chamber, the cover member, and the inner wall of pipes for the gas feeders can be intended to be controlled in the temperature range of 100° C. to 300° C.

Besides, the treatment chamber can be provided with a reaction chamber and a stand-by chamber, and the inner wall of the stand-by chamber can be intended to be cleaned by using a third cleaning gas fed from a third cleaning gas feeder.

In the present invention, the first cleaning gas feeder and the second cleaning gas feeder can be intended to be provided with third and fourth heaters respectively; the temperature of the fourth heater can be controlled to become higher than that of the third heater so that the first cleaning gas as heated by the third heater, and the second cleaning gas as heated by the fourth heater to become higher than the temperature of the first cleaning gas can be separately supplied into the treatment chamber through the above shower head.

Furthermore, the above shower head can comprise a first shower head, and a second shower head as mounted on the periphery of the first shower head so that the treatment gas and the second cleaning gas can be supplied into the treatment chamber through the first shower head, and the first cleaning gas can be supplied into the treatment chamber through the second shower head.

In the invention, a reaction product including ruthenium, ruthenium oxide, osmium, or osmium oxide can be intended to be removed according to the following method: that is, a method of cleaning the treatment chamber, comprising removing the reaction product from the above treatment gas as deposited or adhered on the surfaces of numbers within the treatment chamber by using the first cleaning gas together with the second cleaning gas, wherein the first cleaning gas is supplied into the treatment chamber, with the wafer holder separated from the shower head, and thereafter the second cleaning gas is supplied into the treatment chamber, with the wafer holder approximated to the shower head, so that the treatment chamber can be cleaned.

Besides, the treatment chamber can be provided with a reaction chamber, and a stand-by chamber provided with a third cleaning gas feeder so that a reaction product from a treatment gas as deposited or adhered on the surfaces of members within the stand-by chamber can be removed by using a third cleaning gas.

Furthermore, the step of removing the reaction product with the first cleaning gas, and the step of removing the reaction product with the second cleaning gas can be sequentially carried out, and the inside of the treatment chamber is vacuum-evacuated or purged with nitrogen, between the above two steps.

In the present invention, an oxygen-atom donating gas used as the first or third cleaning gas can comprise at least one gas selected from the group consisting of ozone, oxygen halide, nitrogen oxide, and oxygen molecule, while a halogen-containing gas used as the second cleaning gas can comprise at least one gas selected from the group consisting of chlorine, hydrogen chloride, fluorine, chlorine fluoride, hydrogen fluoride, nitrogen fluoride, bromine, hydrogen bromide, and oxygen halide.

According to the invention mentioned above, when a CVD apparatus for forming on a wafer a film including at least one material selected from the group consisting of, for example, ruthenium, ruthenium oxide, osmium, and osmium oxide by a depositing process is cleaned, or when an etching apparatus for etching the above film so as to form a pattern is cleaned, a reaction product including ruthenium or osmium, which is deposited or adhered on the inner surface of the treatment chamber or the pipe of each of the above apparatus can be effectively removed in a similar manner thereto.

Other objects, features and advantages of the invention will become apparent from the following description of the embodiments of the invention taken in conjunction with the accompanying drawings.

### BRIEF DESCRIPTION OF THE INVENTION

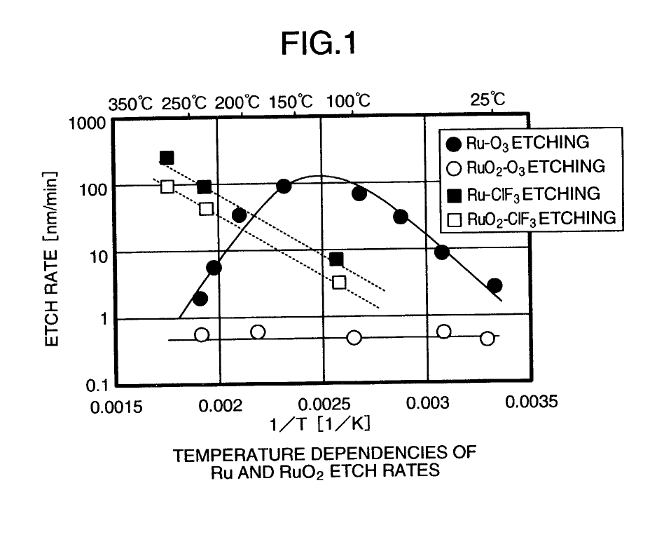

FIG. 1 is a diagram illustrating etching characteristics of each of ozone and chlorine fluoride against a film of each of ruthenium and ruthenium oxide;

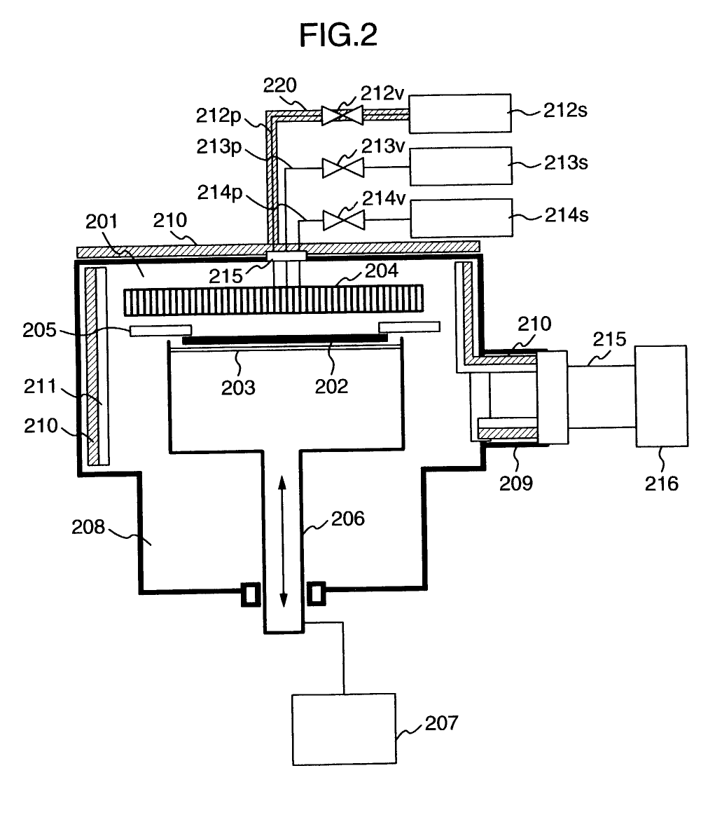

FIG. 2 is a schematic diagram of a treating apparatus, which illustrates Example 1;

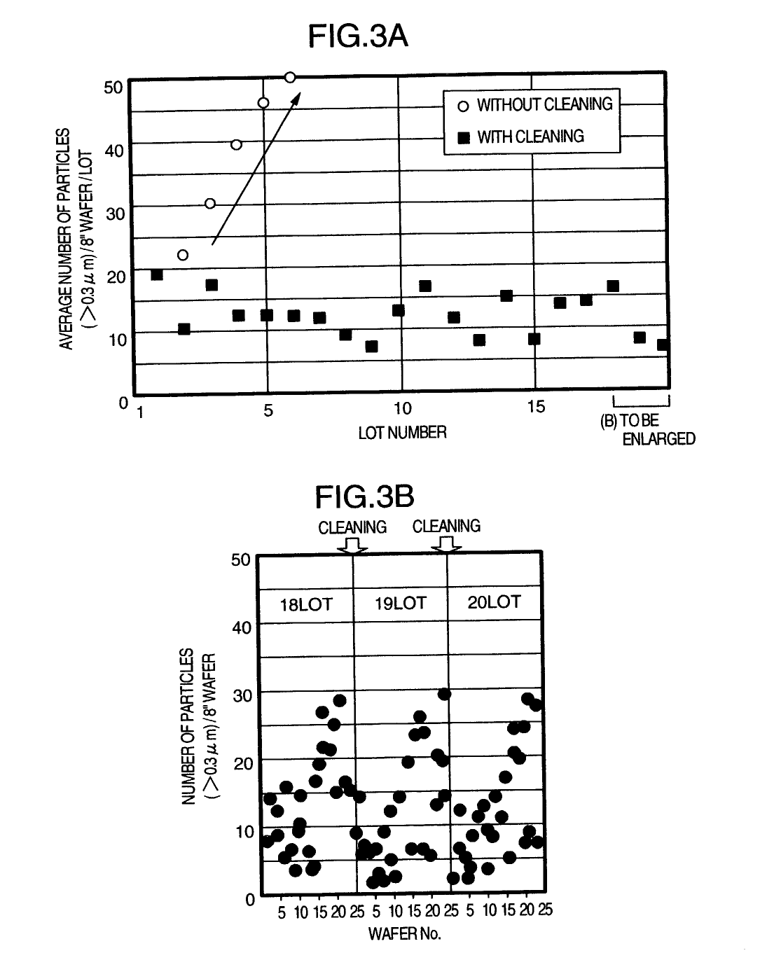

FIG. 3 is a diagram showing the transition of the number of extraneous matters on a wafer, which illustrates the effect of cleaning the inside of a reaction chamber;

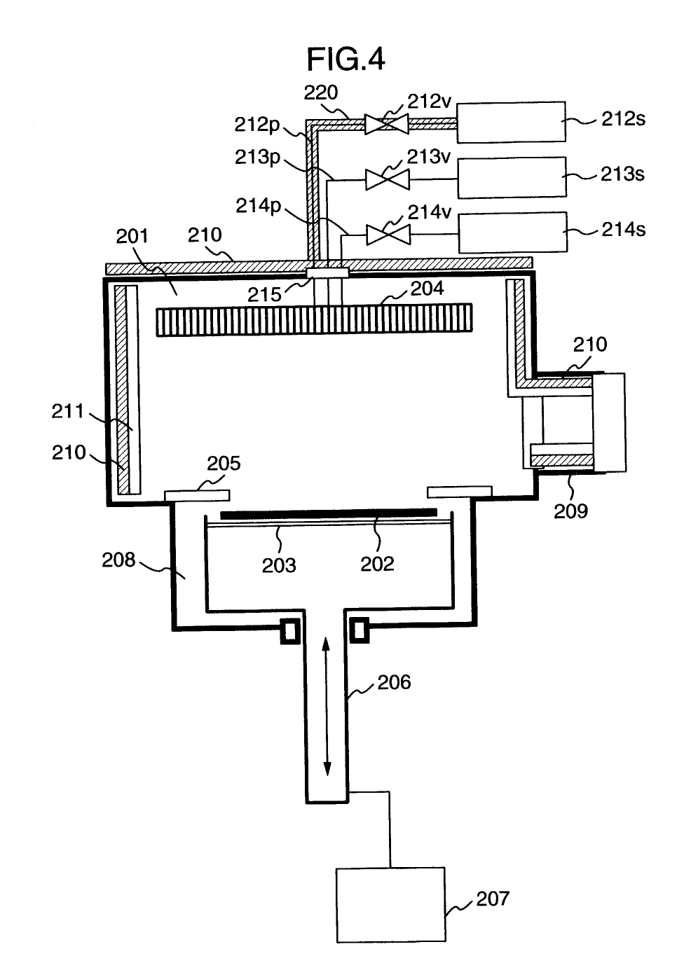

FIG. 4 is a schematic diagram of a treating apparatus, which illustrates an ozone-cleaning in Example 1;

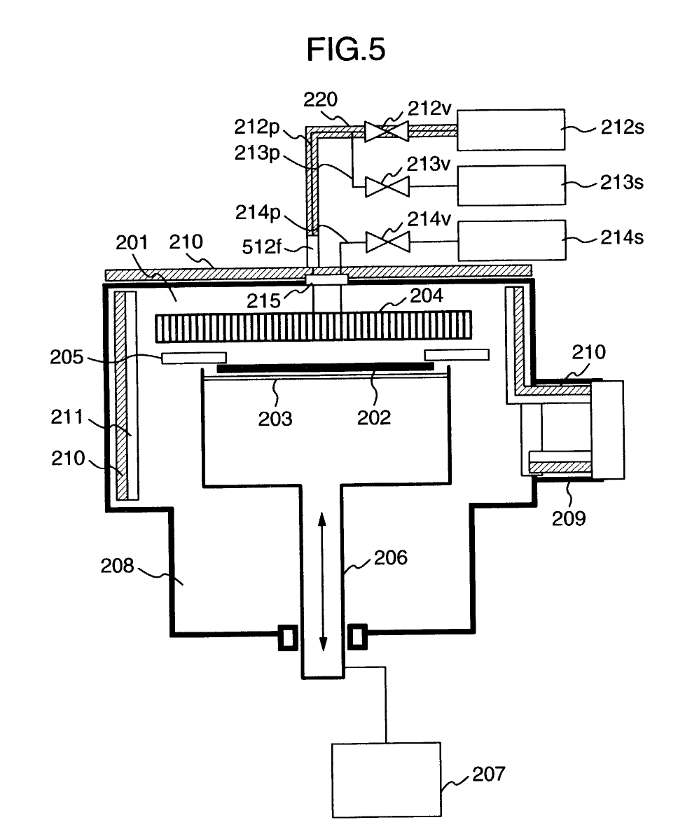

FIG. 5 is a schematic diagram of a treating apparatus, which illustrates Example 2;

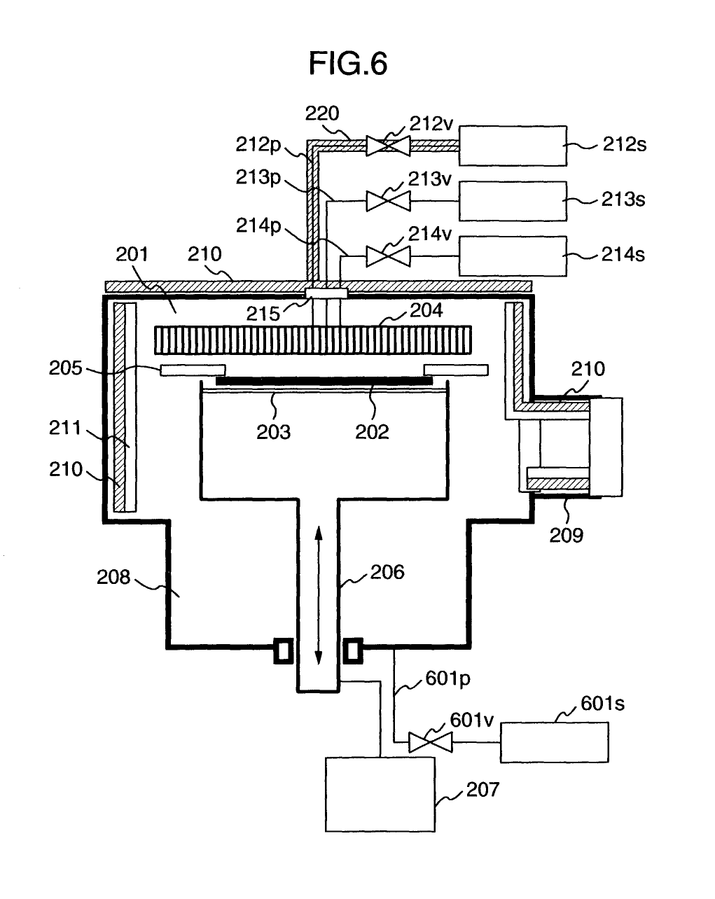

FIG. 6 is a schematic diagram of a treating apparatus, which illustrates Example 3;

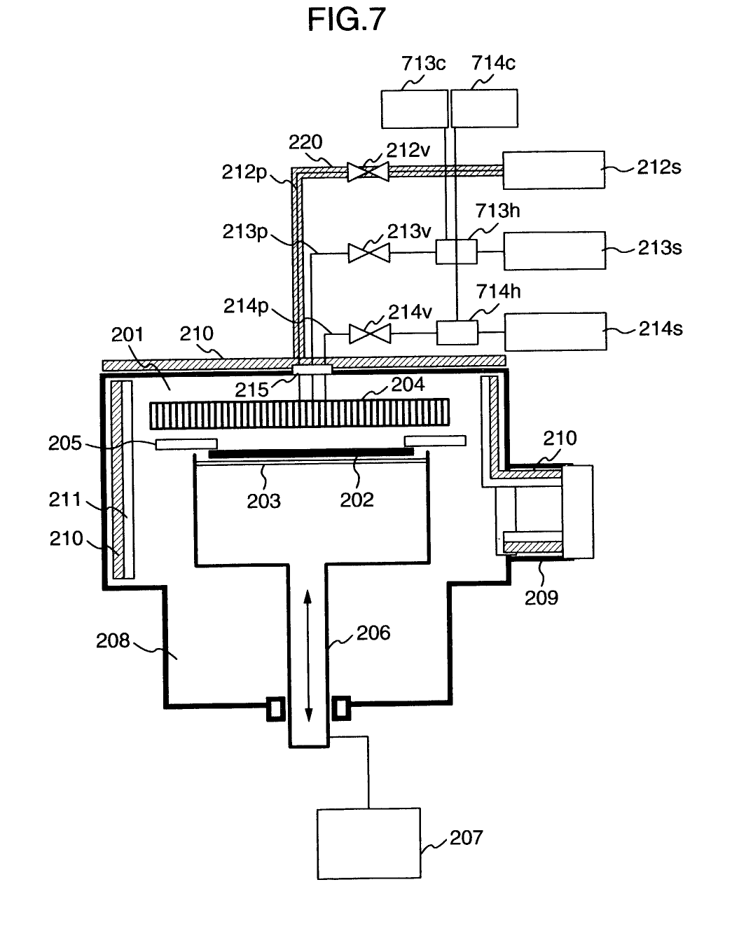

FIG. 7 is a schematic diagram of a treating apparatus, which illustrates Example 4; and

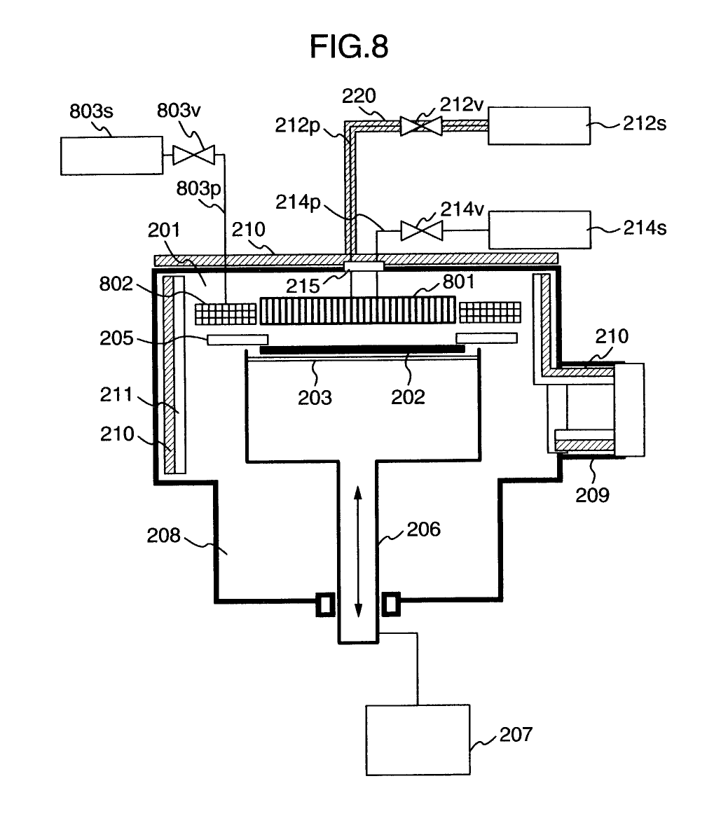

FIG. 8 is a schematic diagram of a treating apparatus, which illustrates Example 5,

### REFERENCE NUMERALS ARE

201 . . . reaction chamber,

202 . . . wafer,

203 . . . wafer holder,

204 . . . shower head,

205 . . . cover plate,

206 . . . driving shaft,

207 . . . control unit,

208 . . . stand-by chamber,

209 . . . exhaust pipe,

210 . . . first heater,

211 . . . cover,

212 . . . feeder for treatment gas (e.g., Ru(EtCp)₂),

212v . . . valve for treatment gas,

212p . . . supply pipe for treatment gas,

213s . . . feeder for first cleaning gas (e.g., ozone gas),

213v . . . valve for first cleaning gas,

213p . . . supply pipe for first cleaning gas

214s . . . feeder for second cleaning gas (e.g., ClF₃),

214v . . . valve for second cleaning gas,

214p . . . supply pipe for second cleaning gas,

215 . . . conductance valve,

216 . . . exhaust system,

220 . . . second heater,

512f . . . filter for treatment gas,

513p . . . supply pipe for first cleaning gas,

601s . . . feeder for third cleaning gas,

601p . . . supply pipe for third cleaning gas,

601v . . . valve for third cleaning gas,

713h . . . third heater,

713c . . . third controller,

714h . . . fourth heater,

714c . . . fourth controller,

801 . . . first shower head,

802 . . . second shower head,

801s . . . feeder for first cleaning gas,

803p . . . supply pipe for first cleaning gas, and

803v . . . valve for first cleaning gas.

### DETAILED DESCRIPTION OF THE INVENTION

Hereinafter, Examples of the present invention will be in detail described with the drawings. Incidentally, the term “a semiconductor device” mentioned below includes a semiconductor device such as a memory device formed on a silicon wafer; a TFT device for liquid crystal display, formed on a quartz or glass wafer; and a device formed on any other wafer except the above wafers. Besides, the term “wafer” includes, but is not limited to, a wafer of a semiconductor such as silicon, on whose surface a semiconductor device is formed; an insulating material wafer or a composite wafer thereof.

Furthermore, the term “ruthenium oxide” means any of RuO, RuO₂, RuO₃ and RuO₄, and the term “osmium oxide” means any of OsO, Os₂O₃, OsO₂₁ OsO₃ and OsO₄.

### EXAMPLE 1

In this Example 1, an example wherein a CVD apparatus for ruthenium was cleaned will be described. First of all, etching characteristics of ruthenium will be illustrated. FIG. 1 illustrates the relation between etch rates of each of a ruthenium film and a ruthenium-oxide film and treating temperatures when each of the ruthenium film and the ruthenium-oxide film was prepared according to a CVD method, and etched by using, for example, ozone gas or chlorine fluoride. With respect to the conditions of an etching with ozone, the concentration of ozone was of 5%, the pressure in the treatment chamber was 100 Torrs, and ozone was generated by means of an ozonizer to which silent discharge is applied. Furthermore, when chlorine fluoride was used, the pressure in the treatment chamber was controlled to 7 Torrs.

As can be clearly taken from this Figure, it has been found that when an etching treatment was carried out with ozone gas, it could be accomplished at a treating temperature of from 20° C. to 300° C., and the etch rate reached a maximum near a temperature of 100° C. to 150° C. The maximum value of etch rates is approximately several times or more the etch rates of a ruthenium film which have been conventionally known, and thus shows an extremely large value. However, it is obvious that the etch rates in a high temperature range of 200° C. or more are remarkably decreased, and it is scarcely etched in a temperature range of 300° C. or more. Secondly, with respect to etching characteristics of a ruthenium-oxide film by using ozone gas, the etch rates thereof are very low in any temperature range, it can be said that it is impossible to etch the ruthenium-oxide film thereby.

On the other hand, when each of the ruthenium film and the ruthenium-oxide film was etched by using hydrogen fluoride, it has been shown that the higher the temperature range in any case of the ruthenium film and the ruthenium-oxide film is, the larger the etch rate of any one of the ruthenium film and the ruthenium-oxide film is.

As described above, if both ozone gas and chlorine fluoride gas can be properly used so as to utilize the difference of an etching reaction by each of ozone gas and chlorine fluoride gas from each other, a reaction product deposited or adhered onto the inside of a treating apparatus can be effectively removed. That is, an area having a relatively low temperature such as an inner wall of a treatment chamber is cleaned by using ozone gas, while an area having a relatively high temperature such as the periphery of a wafer holder loaded with a treatment wafer is cleaned by using chlorine fluoride gas, whereby the inside of the treatment chamber can be evenly cleaned. Additionally, the etch rates were calculated from the characteristic X-ray intensity of ruthenium by means of X-ray fluorescence analysis.

Next, an example wherein the above etching reaction was applied to the cleaning of a CVD apparatus for a ruthenium film will be described. FIG. 2 illustrates a schematic diagram of a CVD apparatus for a ruthenium or ruthenium oxide film. This CVD apparatus comprises a reaction chamber (201) for a deposition reaction; a wafer (202); a wafer holder (203) for heating the wafer (202) and for supporting the wafer (202), wherein a suceptor-heater made of a ceramics-made is integrated; a gas-shower head (204) for homogeneously supplying a depositing gas onto the wafer (202); a cover plate (205) for pressing the wafer (202); a driving shaft (206) for rising and falling the wafer holder (203); a control unit (207) for controlling this vertical drive; and a stand-by chamber (208) for standing-by the wafer holder (203) when the wafer (202) is loaded and unloaded, wherein the combination of the above reaction chamber (201) and the stand-by chamber (208) is referred to as “a treatment chamber”.

The reaction chamber (201) and a pipe (209) for supplying or exhausting a depositing gas are heated by means of first and second heaters (210 and 220) respectively so as to prevent the adsorption of a reaction product. The inner walls within the reaction chamber (201) and the pipe (209) are mounted with covers (211) comprising a material having high resistance properties to a cleaning gas, to which the reaction product is difficult to adsorb, for example, a ceramic material such as aluminum oxide, and quartz. In the same way, the cover (211) for the reaction chamber (201) and the cover (211) for the pipe (209) are heated by means of the first and second heaters (210 and 220) respectively so as to prevent the covers from adsorbing the reaction product. Incidentally, each of the first and second heaters (210 and 220) may be disposed on the outside of each of the reaction chamber (201) and the cover (211), so as to heat the reaction chamber (201) and the cover (211), respectively.

Besides, the wafer holder (203) can rise and fall between the stand-by chamber (208) and the reaction chamber (201).

To the reaction chamber (201), a feeder (212s) which gasifies and feeds Ru(EtCp)₂ wherein EtCp is an abbreviated name for ethylcyclopentadienyl (C₂H₅C₅H₄) ; an O₃ feeder (213s) which is a feeder for a first cleaning gas; and a ClF₃ feeder (214s) which is a feeder for a second cleaning gas are connected through valves (212v, 213v and 214v), and pipes (212p, 213p and 214p) respectively, while the pipe (212p) can be heated by means of the second heater (220). Additionally, a feeder (212s) for depositing gas can also feed N₂ and/or O₂ together with Ru(EtCp)₂.

Furthermore, through the exhaust pipe (209), a conductance valve (215) for controlling a pressure within the reaction chamber (201); and an exhaust system (216) are connected the reaction chamber (201).

This depositing apparatus is that of the cold-wall type wherein the wafer (202) is heated to a temperature of about 200° C. to 750° C. by means of the wafer holder (203) for deposition. When a ruthenium film is deposited with the above depositing gas, the temperature of the heater integrated in the wafer holder (203) is controlled to, for example, 320° C so as to control the temperature of the wafer (202) for deposition to 300° C. Besides, the inner walls of the reaction chamber (201) and the pipes are also heated to about 150° C. by means of the first and second heaters (210 and 220).

However, a by-product of reaction is adhered to the inner wall and the like within the reaction chamber (201), the by-product including ruthenium from the decomposition reaction of the depositing gas and having no use. Furthermore, the size of the wafer holder (203) is rendered to be larger than the size of the wafer (202) so as to homogenize the distribution of temperature of the wafer (202), and a built-in heater is disposed so as to increase the amount of heat charge to the periphery of the wafer (202) wherein the dissipation of heat is large, whereby ruthenium or ruthenium oxide is deposited on the periphery of the wafer holder (203) as well, and it is deposited on a cover plate (205) as well, which is a jig for pressing the wafer (202).

Then, as this CVD process is repeated, these reaction products as deposited or adhered to the inner wall of the reaction chamber (201) and/or the inner wall of the pipe (209) may be released with a curling-up by a gas stream and the like, and then may be adhered onto the wafer (202) during deposition. As a result, the adhered material mentioned above functions as an extraneous matter which may give rise to a disadvantage such as a short circuit, or a breaking of wire when a device pattern has been formed.

Therefore, effects of decreasing such a foreign matter by cleaning the inside of a depositing chamber with ozone and chlorine fluoride were studied according to the following methods:

(1) Method of Depositing Ruthenium Film

First of all, a reaction chamber (201) was evacuated as prescribed; and a wafer (202) was disposed on a wafer holder (203); the temperature of a heater integrated in the wafer holder (203) was set to 320° C. so as to heat the wafer (202) to a temperature of about 300° C., while the temperature of the inner wall of the reaction chamber (201) and the temperature of the inner walls within pipes (209 and 213p) were controlled by means of first and second heaters (210 and 220) respectively so that a temperature of about 150° C. could be provided, at which Ru(EtCp)₂ was neither condensed nor decomposed. Furthermore, the wafer holder (203) and a cover plate (205) were disposed near a shower head (204).

Thereafter, a valve (212v) was opened, Ru(EtCp)₂ and oxygen gas were introduced into the reaction chamber (201) through the shower head (204), and a ruthenium film having a thickness of 0.1 μm was deposited. Besides, the pressure on depositing was controlled by means of a conductance valve (215) so that a predetermined value be provided.

(2) Cleaning Method with Ozone and Chlorine Fluoride

FIG. 3(a) shows the transition of the number of extraneous matters on the wafer (202) when the process for depositing the ruthenium film was terminated. The process for depositing the ruthenium film were applied to 25 pieces of wafers per lot, that is, the deposition process was carried out twenty-five times per lot. When the deposition process for one lot was carried out, the thickness of a built-up ruthenium film as deposited on the periphery of the wafer holder (203) amounted to about 3 μm. As can be clearly taken from this diagram, when the deposition process for a ruthenium film was followed up, the thickness of the built-up film is increased, and then the number of extraneous matters on the wafer (202) is exponentially increased, which corresponds to “WITHOUT CLEANING” shown with white circles in FIG. 3(a). Accordingly, the frequency of cleaning the reaction chamber (201) was at the rate of one time per each lot, that is, the cleaning was carried out each twenty-five times of the deposition process.

Next, the procedure of the cleaning will be explained. First of all, ozone gas was fed into the reaction chamber (201) through the shower head (204) from a first cleaning-gas feeder (213s) in order to quickly clean a ruthenium film which was deposited on an area having a relatively low temperature, such as the inner wall of the reaction chamber (201) and/or a cover (211). Since the wafer holder (203) is retaining a high temperature (i.e., 320° C.) at this time as well as at the time of the deposition process, ozone, which was fed near the wafer holder (203), is easily pyrolyzed, whereby the concentration of ozone provided to the inner wall of the reaction chamber (201) and the like is resultantly and remarkably decreased.

Therefore, as shown in FIG. 4, the wafer holder (203) and a cover plate (205) were lowered to a stand-by chamber (208) so as to prevent the pyrolysis of ozone as much as possible. Specifically, the wafer holder (203) and the cover plate (205) were transferred to the stand-by chamber (208), and thereafter a valve (213v) was opened, ozone gas was fed from the ozone feeder (213s), and then the pressure in the reaction chamber (201) was controlled through a conductance valve.

In the present Example, the concentration of ozone was set to 5%, the flow rate of each gas was set to 10 slm, the pressure in the reaction chamber (201) was set to 10 kPa. The higher the pressure in the reaction chamber is, the larger the rate of cleaning reaction becomes, whereby the more advantageous the throughput becomes. However, when the pressure in the reaction chamber was set to more than atmospheric pressure, it is necessary to provide the constitution of the apparatus wherein countermeasures against the leakage of the cleaning gas are taken, in order to prevent the leakage of the cleaning gas having toxicity out of the apparatus. However, it is not desirable, because such constitution not only makes the apparatus complicated, but also increases the cost of equipment, and thus is not desired as an apparatus for mass production. Therefore, the pressure in the reaction chamber on a cleaning reaction is preferably set to atmospheric pressure or less. On the other hand, when the pressure in the reaction chamber is set to less than 1 kPa for cleaning, a cleaning rate is extremely decreased, and operating efficiency as an apparatus for mass production is decreased, and thus it is desirable to carry out under a pressure of at least 1 kPa.

Next, in order to quickly clean an area having a high temperature, for example, the periphery of the wafer holder (203); the shower head (204); and the cover plate (205) so that a ruthenium film and a ruthenium oxide film deposited thereon can be removed, the area was cleaned with chlorine fluoride. In this case, the wafer holder (203) was again elevated to the position shown in FIG. 2, and thereafter a valve (214v) was opened so as to feed chlorine fluoride into the reaction chamber (201) through the shower head (204) from a feeder for a second cleaning gas (214s). The flow rate of the gas was set to 100 sccm, and the pressure within the reaction chamber (201) was controlled to 1 kPa by means of the conductance valve.

The time of cleaning was controlled by using a method of detecting the termination of cleaning reaction. That is, a mass spectrometer was mounted on a part of an exhaust pipe (209), and the variation per hour of the ionic strength of a reaction-formed gas generated during a cleaning process was determined so as to evaluate the termination of the etching reaction. Specifically, the point of time when the ionic strength of each of RuO₄ and RuF₅ or RuCl₃ was decreased, and thereafter the variation of the ionic strength had been extremely diminished was evaluated as the termination of each cleaning process.

In this Example, the above cleaning process with ozone gas was carried out for a period of about ten minutes; and the feed of ozone gas was stopped; the reaction chamber (201) was once vacuum-evacuated; the cleaning process with chlorine-fluoride gas was carried out for a period of about ten minutes; and then the feed of chlorine-fluoride gas was stopped. In place of vacuum-evacuation, a purging process with nitrogen gas may be carried out. In this Example, a series of processes could be accomplished within about thirty minutes, including the time for controlling the pressure within the reaction chamber (201) and the time for the cleaning process.

Next, a series of steps comprising: forming a ruthenium film, and cleaning the apparatus by using ozone and hydrogen fluoride was repeatedly carried out, and the transition of the number of extraneous matters on wafers (202) of every lot was determined. The case of silicon wafers having a size of 8 inches was taken up as one example, and the results are shown in Figure 3(a), wherein the number of extraneous matters having a size of 0.3 μm or more is shown by a black square symbol, the number being an average value thereof when the deposition process was repeated twenty-five times. In addition, FIG. 3(b) illustrates the transition of the number of extraneous matters of every wafer in a given lot.

As can be clearly taken from these results, as the deposition process for a ruthenium film is repeated, the number of extraneous matters on a wafer gradually increases. However, by cleaning the inside of the apparatus when the deposition process for one lot was terminated, the number of extraneous matters on a wafer in the following lot can be substantially decreased to the initial state. Therefore, by cleaning the inside of the apparatus every lot, the number of extraneous matters on a wafer can be controlled within an allowance, as shown by a black square symbol in FIG. 3(a). Furthermore, since a cleaning method described in this Example can be carried out in a very short period of time, even when the inside of the apparatus is cleaned every deposited lot, the operation efficiency of the apparatus is not decreased, rather the cleaning method not only contributes to the long-term stabilized operation of the apparatus, but also largely contributes to improvements in the yield of the semiconductor devices.

Furthermore, according to the cleaning method described in this Example, an etching process is carried out without plasma, and ozone gas and hydrogen fluoride gas are properly used, and thereby every hole and corner of the inside of the apparatus, that is, all the area to which a cleaning gas is fed can be etched.

Besides, even when a material except ozone, such as oxygen halide, nitrogen oxide, or oxygen atom was used as a first cleaning gas, or even when oxygen or nitrogen oxide was previously excited by ultraviolet rays or plasma, and thereafter introduced into the. reaction chamber, similar effects were provided. Furthermore, even when an halogen gas or halogenated gas except chlorine fluoride, such as chlorine, hydrogen chloride, fluorine, hydrogen fluoride, nitrogen fluoride, bromine, hydrogen bromide, or oxygen halide, was used, or even when the above halogen gas or halogenated gas was previously excited by plasma, and thereafter introduced into the reaction chamber, similar effects were provided.

In this Example, although the cleaning process with hydrogen fluoride gas was carried out after the cleaning process with ozone, even when it was carried out in reverse order, similar effects were provided. Besides, even when a purging process with an inert gas as represented by nitrogen or argon was carried out between the cleaning process with ozone and the cleaning process with hydrogen fluoride, in place of vacuum-evacuation, similar effects were provided.

It goes without saying that the above effects of cleaning the CVD apparatus are similar to those of cleaning the etching apparatus, and even when a substance to be removed by the cleaning process is a ruthenium oxide film, an osmium film or an osmium oxide film without being limited to a ruthenium film, similar effects are provided.

On the other hand, in the treating apparatus as shown in FIG. 2, a hermetic sealing member is used for at least an area having the risk that a treatment gas or cleaning gases may directly come into contact therewith, such as a connection of the reaction chamber (201) to the shower head (204); a connection of the shower head (204) to pipes (212p, 213p, or 214p) for a treatment gas or a cleaning gas; or movable parts between the stand-by chamber (208) and the wafer holder (203). When this sealing member is a metallic sealing material, a Cr—Ni alloy or a Fe—Cr—Ni alloy which has ozone-gas resistance properties and a Ni-content of 90% or less, or an Au-coated metal is used, while a pure-Ni sealing member as commonly used is not used. Furthermore, when the sealing member is a rubber sealing-member, fluorine-contained rubber having a molar ratio of the number of hydrogen atoms to the number of carbon atoms being 10% or less is used, while Viton or the like, which has lower ozone-gas resistance properties and has a molar ratio of the number of hydrogen atoms to the number of carbon atoms being more than 10%, is not used, whereby the apparatus can be stably operated.

### Example 2

FIG. 5 shows a schematic diagram of a CVD apparatus for a ruthenium film or a ruthenium oxide film, as Example 2. The difference between the apparatus in this Example and the one in Example 1 lies in a system for feeding gases. However, the other structures of the apparatus in Example 2 are the same as the ones in Example 1. In Example 2, 212s is a feeder for a treatment gas, 212v is a valve mounted to a supply pipe for the treatment gas, 212p is the supply pipe for the treatment gas, 512f is a filter mounted in the midway of the pipe, and these are heated in the temperature range of 100° C. to 200° C. by means of a second heater (220), while 213s is a feeder for a first cleaning gas (e.g., ozone gas), 213p is a supply pipe for the first cleaning gas, and this supply pipe (213p) is connected to the supply pipe (212p) for the treatment gas on the downstream side of the valve (212v).

The above apparatus was used to form a ruthenium film according to a deposition process similar to the one described in Example 1. As a result, a condensation product or decomposition product of a treatment gas was adhered to the inner wall of the supply pipe (212p) for the treatment gas. These adhered material will give rise to an extraneous matter onto a wafer, or to clogging in the filter (512f), which will give rise to variation of the flow rate of a gas and/or variation of the thickness of a film.

Then, a deposition process was carried out about twenty-five times so as to form ruthenium films, and thereafter a cleaning process was carried out with ozone and chlorine fluoride, and effects thereof was considered. First of all, after the deposition process was terminated, the valve (213v) for supplying a first cleaning gas was opened, and ozone gas, which is the first cleaning gas, was supplied into the reaction chamber (201). By supplying ozone gas thereinto, a deposit adhered to an area having a relatively low temperature within the reaction chamber (201) could be removed as described in Example 1, while the inside of the supply pipe (212p) for the treatment gas could be cleaned as well.

There is a problem with a halogen gas of corroding the inner wall of the supply pipe (212p) for the treatment gas. However, since ozone gas can clean the inside of the supply pipe without corroding the same, the inside of the supply pipe (212p) can be cleaned without generating a metal contamination from corrosion. Incidentally, when the cleaning process with ozone is carried out, conditions concerning a pressure, a flow rate, and a temperature within the reaction chamber are similar to the ones described in Example 1.

After the cleaning process was carried out with ozone gas, the inside of the reaction chamber (201) was vacuum-evacuated, and chlorine fluoride as a second cleaning gas was fed into the reaction chamber (201), whereby a ruthenium film and/or a ruthenium oxide film deposited on the member of an area having a relatively high temperature were removed, and the member was cleaned. Then, the conditions of the cleaning process were similar to the ones described in Example 1.

As shown in this Example, a series of operations comprising the deposition process for a ruthenium film, and the cleaning process was repeated, and then the transition of the number of extraneous matters on the wafer (202) was determined. As a result, the increase of the number of extraneous matters deposited on the wafer could be controlled in the same manner as shown in FIG. 3.

According to this Example, not only the inner wall of the treatment chamber but also the inside of the treatment gas supply-pipes could be cleaned, and thus the occurrence of extraneous matters from deposits within the apparatus in the process for forming the ruthenium film could be controlled in the long time, whereby a always stabilized deposition process is realized, and the deposition process can contribute to the improvement of the yield of semiconductor devices.

### Example 3

FIG. 6 is a schematic diagram of a treating apparatus for forming a ruthenium film or a ruthenium oxide film, as Example 3. The difference between the apparatus in this Example and the one in Example 1 or Example 2 lies in that a stand-by chamber (208) which constitutes a part of a treatment chamber (201) is provided with a feeder (601s) for a third cleaning gas, a supply pipe (601p) for the third cleaning gas, and a valve (601v) for the third cleaning gas. Incidentally, in this Example, ozone gas was used as the third cleaning gas as well as a first cleaning gas.

When a ruthenium film is formed on a wafer (202) by a deposition process, a treatment gas is fed into the reaction chamber (201), with a wafer holder (203) being in proximity to a shower head (204). At this time, since the treatment gas fed into the reaction chamber (201) is dispersed into the stand-by chamber (208), the treatment gas and/or a decomposed matter thereof are condensed, adhered or deposited onto the wall surface of the stand-by chamber (208) and/or the surface of a protective cover as well. When these adhered materials and/or deposits are introduced and/or taken out, or when the pressure within the treatment chamber is controlled, they curl up, and resultantly easily form extraneous matters on the wafer (202).

Therefore, after the ruthenium film was formed by the deposition process, a cleaning process was carried out according to the following procedure. That is to say, the wafer holder (203) was stored in the stand-by chamber (208), and thereafter the first cleaning gas was fed into the reaction chamber (201) from a feeder (213s) for the first cleaning gas, while the third cleaning gas was fed into the stand-by chamber (208) from a feeder (601s) for the third cleaning gas. Thereafter the inside of the reaction chamber was cleaned with a second cleaning gas according to a similar manner to the one described in Example 1 or Example 2. Incidentally, as the first and third cleaning gases, ozone gas was used.

In this Example, effects of cleaning the inside of the treatment chamber are similar to the ones described in Example 1 or Example 2. In particular, ozone gas was fed into the stand-by chamber as well, whereby the ruthenium film adhered and/or deposited on the inner wall of the stand-by chamber could be effectively removed, and thus the number of extraneous matters on the wafer could be further decreased. Furthermore, operation procedures including a process for cleaning the inside of the stand-by chamber are not limited to the ones mentioned above. The reaction chamber and the stand-by chamber may be individually operated. The operation procedures also may be carried out with the wafer holder transferred. Furthermore, it goes without saying that even when the processes with the first and third cleaning gases and the process with the second cleaning gas are in reverse order, similar effects are provided.

### Example 4

FIG. 7 is a schematic diagram of a depositing apparatus for explaining Example 4. The difference between the apparatus in this Example and the one in Example 1, 2 or 3 lies in that a feeder (213s) for a first cleaning gas or a supply pipe (213p) therefor is provided with a third heater (713h); a feeder (214s) for a second cleaning gas or a supply pipe (214p) therefor is provided with a fourth heater (714h); and the third heater (713h) and the fourth heater (714h) are provided with control units (713c and 714c) respectively, the control units (713c and 714c) independently controlling the temperatures of these heaters (713h and 714h), respectively.

Effects of cleaning the above apparatus were studied by using the same. When the inside of a reaction chamber (201) was cleaned with the first cleaning gas (e.g., ozone gas), the first cleaning gas feeder (213s) or the supply pipe (213p) was heated to about 100° C. This is, because as shown in FIG. 1, the etch rate of a ruthenium film with ozone gas is larger in the temperature range of about 50° C. to about 200° C., preferably 100° C. to 150° C., and the cleaning process can be carried out with a more active ozone gas by feeding ozone gas heated (for example, to 100° C.) into the reaction chamber (201). Incidentally, since when ozone gas is heated to a temperature of more than 200° C., it is lost by its thermal decomposition, the heat temperature is preferably in the range of 200° C. or less. Besides, the conditions of feeding a heated ozone gas and the conditions of the cleaning process are the same as the ones described in Example 1, 2 or 3.

Next, when the cleaning process was carried out by using the second cleaning gas (e.g., chlorine fluoride), the feeder (214s) for the second cleaning gas, and the supply pipe (214p) were heated to a temperature of about 250° C. by means of the heater (714h). This is, because as shown in FIG. 1, the higher the temperature of chlorine fluoride becomes, the larger the etch rate for the ruthenium film becomes. However, when the supply pipe (214p) for chlorine fluoride is heated to about 300° C. or more, the pipe (214p) may be reacted with chlorine fluoride so that the pipe (214p) may easily corroded. Therefore, in the light of etch rate, the heat temperature is desirably in the order of 200° C. to 300° C.

Furthermore, from the results of the etching process, it has been found that in order to efficiently remove a ruthenium film and/or a ruthenium oxide film as deposited on the inside of the reaction chamber and/or the member provided therein, the second cleaning gas (i.e., chlorine fluoride) is preferably heated to a higher temperature than the first cleaning gas (i.e., ozone gas) for feeding.

In this Example, excellent cleaning effects similar to the ones described in Example 1 was recognized.

### Example 5

FIG. 8 shows a schematic diagram of a treating apparatus, as Example 5. The structure of the apparatus are almost the same as the one shown in FIG. 2, except that gas-feeding shower-heads thereof are different from each other. That is, in-this Example, the shower head has a double structure, which comprises a first inside shower head (801) having approximately same dimension as that of a wafer holder (203), and a second shower head (802) disposed on the periphery of the first shower head (801), whose periphery dimension is approximately the same as that of a cover plate (205) or larger than that of the cover plate (205). In addition, the first shower head (801) is provided with a supply system for a treatment gas and a supply system for a second cleaning gas (hydrogen fluoride gas), while the second shower head (802) is provided with a feeder (803s) for a first cleaning gas (ozone gas), a supply pipe (803p) and a supply valve (803v).

The above treating apparatus was used so as to form a ruthenium film by a deposition process in a similar manner to the one described in Example 1, and effects of cleaning the above apparatus were studied. At this time, since ozone gas can be more directly supply onto the inner wall of the reaction chamber (201) and the like from the second shower head (802), the inside of the apparatus can be more effectively cleaned, as compared with the apparatus in Example 1.

On the other hand, since the cleaning process with chlorine fluoride is carried out by supplying chlorine fluoride from the first shower head (801), a reaction product as adhered or deposited on the surface of a member having a higher temperature can be effectively removed in a similar manner to the one described in Example 1.

In addition, since ozone gas is fed into the reaction chamber (201) from the second shower head (802), the influence of members having a high temperature, for example, a wafer holder (203) and a cover plate (205), can be minimized, the cleaning process can be carried out, with the wafer holder (203) being in close vicinity to the first shower head (801), whereby the vertical motion of the wafer holder (203) depending upon the kind of a cleaning gas as carried out in Example 1 may be omitted.

As mentioned above, by properly using ozone gas and hydrogen fluoride gas, a ruthenium and/or an oxide thereof which are adhered or deposited onto members in a treating apparatus can be remarkably effectively removed. Hereby, not only the number of extraneous materials on a wafer can be drastically decreased, but also the continuous operation of a treating apparatus, the improvement of the apparatus in operation rate, and the improvement of a semiconductor device in yield can be provided.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A semiconductor treating apparatus, comprising a treatment chamber, a vertically movable wafer holder, a shower head, a treatment gas feeder, a first cleaning gas feeder, and a second cleaning gas feeder, wherein a treatment gas fed from the treatment gas feeder, and a first cleaning gas and a second cleaning gas fed from the first cleaning gas feeder and the second cleaning gas feeder, respectively, are fed into the treatment chamber through the shower head, and when the first cleaning gas is fed from the first cleaning gas feeder, the wafer holder is allowed to be separated from the shower head.

2. A semiconductor treating apparatus, comprising a treatment chamber, a wafer holder, a shower head, a treatment gas feeder, a first cleaning gas feeder, and a second cleaning gas feeder, wherein the shower head comprises a first shower head and a second shower head provided on a periphery of the first shower head so that a treatment gas fed from the treatment gas feeder, and a second cleaning gas fed from the second cleaning gas feeder be fed into the treatment chamber through the first shower head, and a first cleaning gas fed from the first cleaning gas feeder be fed into the treatment chamber through the second shower head.

3. A semiconductor treating apparatus according to claim 1, wherein the treatment chamber comprises a cover member and a first heater, the cover member being mounted to cover an inner wall of the treatment chamber, the first heater being the one to heat the inner wall of the treatment chamber and the cover member, wherein the treatment gas feeder comprises a second heater, and a temperature of each of the inner wall of the treatment chamber, the cover member, and the inner wall of a pipe for each of the gas feeders is controlled.

4. A semiconductor treating apparatus according to claim 3, wherein the temperature of each of the inner wall of the treatment chamber, the inner wall of the cover member, and the inner wall of a pipe for each of the gas feeders is controlled in the range of 100° C. to 300° C.

5. A semiconductor treating apparatus according to claim 1, wherein the first cleaning gas feeder is connected to the pipe for the treatment gas feeder.

6. A semiconductor treating apparatus according to claim 1, wherein the treatment chamber comprises a reaction chamber and a stand-by chamber, the stand-by chamber is provided with a third cleaning gas feeder, and a third cleaning gas is the same as the first cleaning gas.

7. A semiconductor treating apparatus according to claim 1, wherein the first cleaning gas feeder and the second cleaning gas feeder are provided with a third heater and a fourth heater, respectively, and the temperature of the fourth heater is controlled to become higher than the temperature of the third heater.

8. A semiconductor treating apparatus according to claim 7, wherein the treatment gas fed from the treatment gas feeder, the first cleaning gas heated by the third heater, and the second cleaning gas heated by the fourth heater to become higher than the temperature of the first cleaning gas are fed into the treatment chamber through the shower head.

9. A semiconductor treating apparatus according to claim 7, wherein the first cleaning gas is fed into the treatment chamber, while the first cleaning gas is heated to a temperature range of 20° C. to 200° C. by the third heater.

10. A semiconductor treating apparatus according to claim 7, wherein the second cleaning gas is fed into the treatment chamber, while the second cleaning gas is heated to a temperature range of 200° C. to 300° C. by the fourth heater.

11. A semiconductor treating apparatus according to claim 1, wherein a metallic sealing material having a Ni-content of 90% or less is used on at least a connection of the treatment chamber to the shower head, a connection of the shower head to the treatment gas pipe or pipes for the cleaning gases, or movable parts between the stand-by chamber forming a part of the treatment chamber and the wafer holder, or the like.

12. A semiconductor treating apparatus according to claim 1, wherein a rubber sealing member comprising rubber having a molar ratio of the number of hydrogen atoms to the number of carbon atoms of 10% or less is used on at least a connection of the treatment chamber to the shower head, a connection of the shower head to the treatment gas pipe or pipes for the cleaning gases, or movable parts between the treatment chamber and the wafer holder.

13. A semiconductor treating apparatus according to claim 1, wherein the first cleaning gas comprises at least one gas selected from the group consisting of ozone, oxygen halide, nitrogen oxide, oxygen molecule.

14. A semiconductor treating apparatus according to claim 1, wherein the second cleaning gas is a gas containing a halogen.

15. A semiconductor treating apparatus according to claim 1, wherein the second cleaning gas comprises at least one gas selected from the group consisting of chlorine, hydrogen chloride, fluorine, chlorine fluoride, hydrogen fluoride, nitrogen fluoride, bromine, hydrogen bromide, and oxygen halide.

16. A semiconductor treating apparatus according to claim 1, wherein the first cleaning gas is an oxygen-atom donating gas, and the second cleaning gas is a gas containing a halogen.

17. A semiconductor treating apparatus according to claim 1, wherein the treatment chamber conducts a treatment of a metallic material including at least ruthenium or osmium, or a compound material thereof.

18. A semiconductor treating apparatus according to claim 1, wherein in the treatment chamber, a thin film comprising at least one component selected from the group consisting of ruthenium, ruthenium oxide, osmium, and osmium oxide is formed on a wafer mounted upon the wafer holder.

19. A semiconductor treating apparatus according to claim 1, wherein a thin film comprising at least one component selected from the group consisting of ruthenium, ruthenium oxide, osmium, and osmium oxide is etched in the treatment chamber, the thin film being formed on a wafer mounted upon the wafer holder.

20. A method of cleaning a semiconductor treating apparatus comprising a treatment chamber, a wafer holder, a shower head, a treatment gas feeder, a first cleaning gas feeder, and a second cleaning gas feeder, which comprises the steps of:
removing with a first cleaning gas a reaction product from a treatment gas, which is deposited or adhered on the surface of a member within the treatment chamber; and
removing with a second cleaning gas the same.

21. A method of cleaning a semiconductor treating apparatus comprising a treatment chamber, a wafer holder having a vertically movable means, a shower head, a treatment gas feeder, a first cleaning gas feeder, and a second cleaning gas feeder, which comprises the steps of:
separating the wafer holder from the shower head, and supplying the first cleaning gas into the treatment chamber, and thereafter removing a reaction product from the treatment gas, which is deposited or adhered on the surface of a member within the treatment chamber; and
approximating the wafer holder to the shower head, and supplying the second cleaning gas into the treatment chamber, and thereafter removing the reaction product.

22. A method of cleaning a semiconductor treating apparatus according to claim 20, wherein the treatment chamber comprises a reaction chamber and a stand-by chamber provided with a third cleaning gas feeder, and the reaction product from the treatment gas, which is deposited or adhered on the surface of a member within the stand-by chamber, is removed with a third cleaning gas.

23. A method of cleaning a semiconductor treating apparatus according to claim 20, wherein the step of removing the reaction product with the first cleaning gas and the step of removing the reaction product with the second cleaning gas are continuously carried out.

24. A method of cleaning a semiconductor treating apparatus according to claim 23, further comprising the step of vacuum-evacuating the treatment chamber, between the step of removing the reaction product with the first cleaning gas and the step of removing the reaction product with the second cleaning.

25. A method of cleaning a semiconductor treating apparatus according to claim 23, further comprising the step of purging the treatment chamber with an active gas, between the step of removing the reaction product with the first cleaning gas and the step of removing the reaction product with the second cleaning.

26. A method of cleaning a semiconductor treating apparatus according to claim 20, wherein the first cleaning gas comprises at least one gas selected from the group consisting of ozone, oxygen halide, nitrogen oxide, oxygen molecule.

27. A method of cleaning a semiconductor treating apparatus according to claim 20, wherein the second cleaning gas is a gas containing a halogen.

28. A method of cleaning a semiconductor treating apparatus according to claim 20, wherein the second cleaning gas comprises at least one gas selected from the group consisting of chlorine, hydrogen chloride, fluorine, chlorine fluoride, hydrogen fluoride, nitrogen fluoride, bromine, hydrogen bromide, and oxygen halide.

29. A method of cleaning a semiconductor treating apparatus according to claim 20, wherein the first cleaning gas is an oxygen-atom donating gas, while the second cleaning gas is a gas containing a halogen.

30. A method of cleaning a semiconductor treating apparatus according to claim 20, wherein the temperature of each of the inner wall of the treatment chamber, the inner wall of the cover member, the inner walls of the gas feeders is controlled to be in the range of 100° C. to 300° C.

31. A method of cleaning a semiconductor treating apparatus according to claim 20, wherein when the first cleaning gas is fed, the pressure within the treatment chamber is controlled to be in the range of from 1 kPa to atmospheric pressure.

32. A method of cleaning a semiconductor treating apparatus according to claim 20, wherein the first cleaning gas is heated to the temperature range of 20° C. to 200° C. by means of a third heater mounted on the first cleaning gas feeder, and fed into the treatment chamber.

33. A method of cleaning a semiconductor treating apparatus according to claim 20, wherein the second cleaning gas is heated to the temperature range of 200° C. to 300° C. by means of a fourth heater mounted on the second cleaning gas feeder, and fed into the treatment chamber.

34. A method of cleaning a semiconductor treating apparatus according to claim 20, wherein the treatment chamber conducts a treatment of a metallic material including at least ruthenium or osmium, or a compound material thereof.

35. A method of cleaning a semiconductor treating apparatus according to claim 20, wherein in the treatment chamber, a thin film comprising at least one component selected from the group consisting of ruthenium, ruthenium oxide, osmium, and osmium oxide is formed on a wafer mounted upon the wafer holder.

36. A method of cleaning a semiconductor treating apparatus according to claim 20, wherein a thin film comprising at least one component selected from the group consisting of ruthenium, ruthenium oxide, osmium, and osmium oxide is etched in the treatment chamber, the thin film being formed on a wafer mounted upon the wafer holder.
